(19) United States
(12) Patent Application Publication
(10) Pub. No.: US 2010/0096086 A1
(43) Pub. Date: Apr. 22, 2010

(54) Device for the Pre- and/or Aftertreatment of a Component Surface by Means of a Plasma Jet

(76) Inventors: Michael Minkow, Berlin (DE); Olaf Hoyer, Oberkramer (DE); Henning Gleich, Duisburg (DE); Matthias Schulenburg, Berlin (DE)

Correspondence Address: NOTARO & MICHALOS P.C., 100 DUTCH HILL ROAD, SUITE 110, ORANGEBURG, NY, 10962-2100, US

(21) Appl. No.: 12/567,344

(22) Filed: Sep. 25, 2009

(30) Foreign Application Priority Data
Oct. 20, 2008 (DE) 102008052102.7-54

(51) Int. Cl. H01L 21/3065

(52) U.S. Cl. 156/345.35

(57) ABSTRACT

The invention relates to a device for the pre- and/or aftertreatment of a component surface by means of a plasma jet, particularly by means of a jet of an atmospheric plasma, with a plasma head (1) forming a plasma generator with voltage and carrier-gas supply, to which plasma head a nozzle tube (8) of a plasma nozzle (7) is connected, which plasma nozzle encompasses a plasma electrode (17) of the plasma generator, which is electrically insulated with respect to the plasma nozzle, and is connected in terms of flow technology to a working gas channel (19) and has a nozzle head (11) with an outlet opening (12) for the plasma jet at its end (9) opposite to the plasma head (1), wherein the tip (18) of the plasma electrode (17) is arranged set back in the direction of the longitudinal axis (13) of the plasma nozzle (7) with respect to the outlet opening (12) of the nozzle head (11).

In order to take care of a defined treatment of the surface and simultaneous application of at least one adhesive component onto the component surface in a space- and time-saving manner
the outlet opening (12) of the nozzle head (11) for the plasma jet of the plasma nozzle (7) is arranged offset in the radial direction to the longitudinal axis (13) thereof, and
a dosing nozzle (20) with at least one discharge opening (24;25) is provided for applying at least

one adhesive, which dosing nozzle is connected to the plasma head (1), extends through the plasma nozzle in the direction of the longitudinal axis (13) of the plasma nozzle (7) and has at least one attachment (26) accessible from outside of the plasma head (1) for dosing the at least one adhesive, the at least one discharge opening (24; 25) of which dosing nozzle is arranged offset outwards in the direction of the longitudinal axis (13) of the plasma nozzle (7), beyond the outlet opening (12) of the nozzle head (11) for the plasma jet and is also arranged offset radially inwards to the longitudinal axis

of the plasma nozzle (7) in relation to the outlet opening (12) for the plasma jet of the nozzle head (11).

### FIELD AND BACKGROUND OF THE INVENTION

The invention relates to a device for the pre- and/or aftertreatment of a component surface by means of a plasma jet, particularly by means of a jet of an atmospheric plasma, with a plasma head forming a plasma generator with voltage and carrier-gas supply, to which plasma head a nozzle tube of a plasma nozzle is connected, which plasma nozzle encompasses a plasma electrode of the plasma generator, which is electrically insulated with respect to the plasma nozzle, and is connected in terms of flow technology to a working gas channel and has a nozzle head with an outlet opening for the plasma jet at its end opposite to the plasma head, wherein the tip of the plasma electrode is arranged set back in the direction of the longitudinal axis of the plasma nozzle with respect to the outlet opening of the nozzle head.

A device of this type known from WO 2005/117507 (PCT/EP2005/005792) is used for removing an inorganic layer from a component such as e.g. a motor vehicle headlight by means of a plasma jet directed onto the inorganic layer, which plasma jet is to be generated with the aid of an atmospheric discharge in a working gas containing a reactive gas. The working gas channel has a plurality of separate openings which are arranged around the nozzle opening in order to generate a plasma which is free of discharge streams. Thus, a surface, onto which surface an adhesive is to be applied with an independent application apparatus in a subsequent operation, is uncovered e.g. at the edge region of the motor vehicle headlight with the known device, if a cover plate is to be adhesively bonded to the uncovered surface at the edge region of the motor vehicle headlight.

A device with an application unit for at least one component, around which device a plurality of elements for a simultaneous surface pretreatment are externally arranged in an annular manner, is furthermore known (DE 20 2005 00 6 266 U1) for applying reactive plastics onto a component surface. These elements, which may be flaming nozzles, plasma generators, corona discharge heads or spray valves for applying adhesion promoters, are switchable in accordance with the processing direction by means of a control for surface pretreatment, whereby, in one operation, a surface around the application unit can be seamlessly pretreated and the plastic can subsequently be applied onto the pretreated surface by means of an application nozzle of the application unit. The elements for the surface treatment can consist of straight segments and be provided in a square or hexagonal shape around the application unit.

### SUMMARY OF THE INVENTION

The object of the invention is to make available a device of the type mentioned at the beginning for pre- and/or aftertreatment of a component surface by means of a plasma jet, using which device a defined treatment of the surface and a simultaneous application of at least one adhesive component onto the component surface can be ensured in a space- and time-saving manner and with a high degree of process reliability.

This object is achieved according to the invention, in that
the outlet opening for the plasma jet of the nozzle head of the plasma nozzle is arranged offset in the radial direction to the longitudinal axis thereof, and
a dosing nozzle with at least one discharge opening is provided for applying at least one adhesive, which dosing nozzle is connected to the plasma head, extends through the plasma nozzle in the direction of the longitudinal axis of this plasma nozzle and has at least one attachment accessible from outside of the plasma head for dosing the at least one adhesive, the at least one discharge opening of which dosing nozzle is arranged offset outwards in the direction of the longitudinal axis of the plasma nozzle, beyond the outlet opening for the plasma jet of the nozzle head of the plasma nozzle and is also arranged offset radially inwards to the longitudinal axis of the plasma nozzle in relation to the outlet opening for the plasma jet of the nozzle head.

Preferably, a dividing wall which extends over the axial length of the dosing nozzle is preferably provided within the dosing nozzle, by means of which dividing wall the dosing nozzle is subdivided into two longitudinal chambers which have a discharge opening in each case, which longitudinal chambers in each case have an attachment for the separate dosing of two adhesive components which are different from one another, which attachment can be accessed from outside of the plasma head. The outlet opening of the nozzle head for the plasma jet can be formed in a circular manner.

Preferably, the nozzle tube of the plasma nozzle is connected to the plasma head by means of a pivot bearing and is to be set rotating about its longitudinal axis by a motor, wherein the outlet opening of the nozzle head describes a circular path for the plasma jet. Preferably, the dosing nozzle is arranged coaxially in the plasma nozzle.

The device according to the invention ensures, with a high degree of process reliability, a defined plasma pre- and/or aftertreatment of the component surface in combination with the possible application of two adhesive systems which cure at different speeds by positioning a plasma nozzle and a dosing nozzle, which is encompassed by the plasma nozzle, for the adhesive application within a processing head which can be controlled robotically. If a fast fixing is not necessary on the plasma-pretreated component surface, then the subsequent application of only one adhesive onto the processed component surface by means of the dosing nozzle is required.

For low investment costs, the device according to the invention enables a reduction of the process time, enables an improvement of the adhesion between the substrate and adhesive and therefore the achievement of greater strengths and brings about a good reproducibility of the adhesive properties by means of the plasma pretreatment of the surfaces.

### BRIEF DESCRIPTION OF THE DRAWINGS

Preferred embodiments of the device according to the invention are now explained on the basis of the drawings. In the drawings:

FIG. 1 is the view of a longitudinal section of a schematically illustrated first embodiment of the device, wherein the nozzle tube of the plasma nozzle is rotatably mounted on the plasma head by means of a pivot bearing,

FIG. 2 is a view of the first embodiment according to FIG. 1, seen from below,

FIG. 3 is the view of a longitudinal section of a schematically illustrated second embodiment of the device, wherein the nozzle tube of the plasma nozzle is fixedly connected to the plasma head and the outlet opening of the nozzle head is constructed in a circular manner, and

FIG. 4 is a view of the second embodiment according to FIG. 3, seen from below.

### DETAILED DESCRIPTION

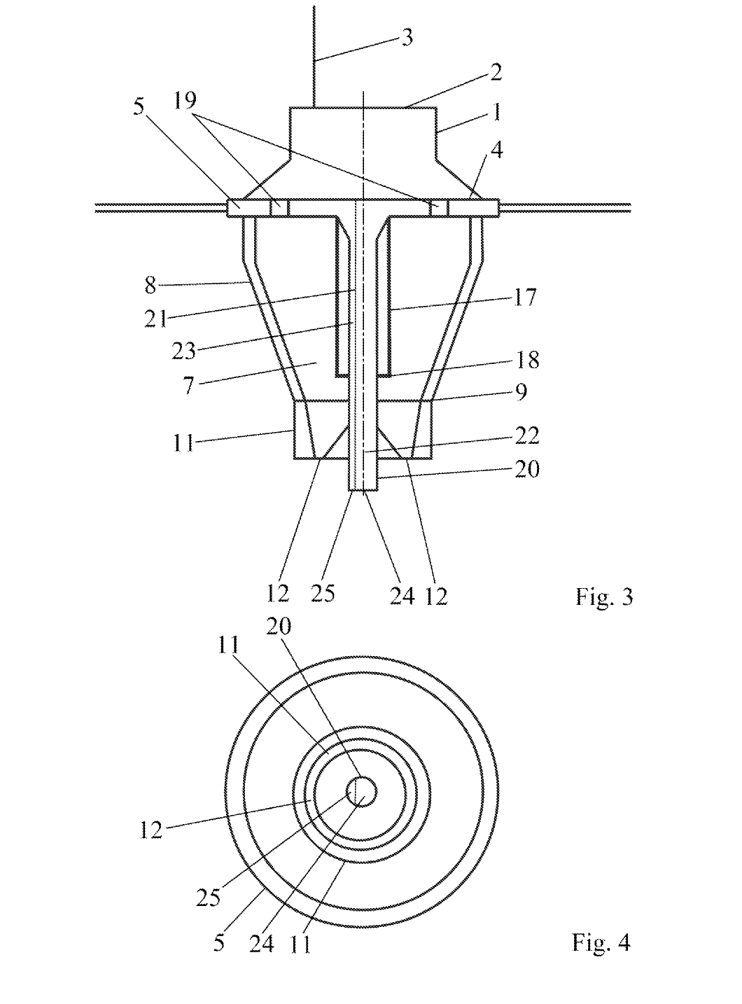

As can be drawn from the FIGS. 1 and 3, the device has a plasma head 1 which forms a plasma generator, which plasma head can be guided by a robot (not illustrated) and is provided with voltage and carrier gas supply lines 3 on its upper side 2. A plate-like carrier unit 5 is provided on the opposite underside 4 of the plasma head 1. A plasma nozzle 7 has a nozzle tube 8 which merges into a nozzle head 11 for the plasma jet at its lower end 9. The nozzle head 11 has an excentrically arranged outlet opening 12 for the plasma jet.

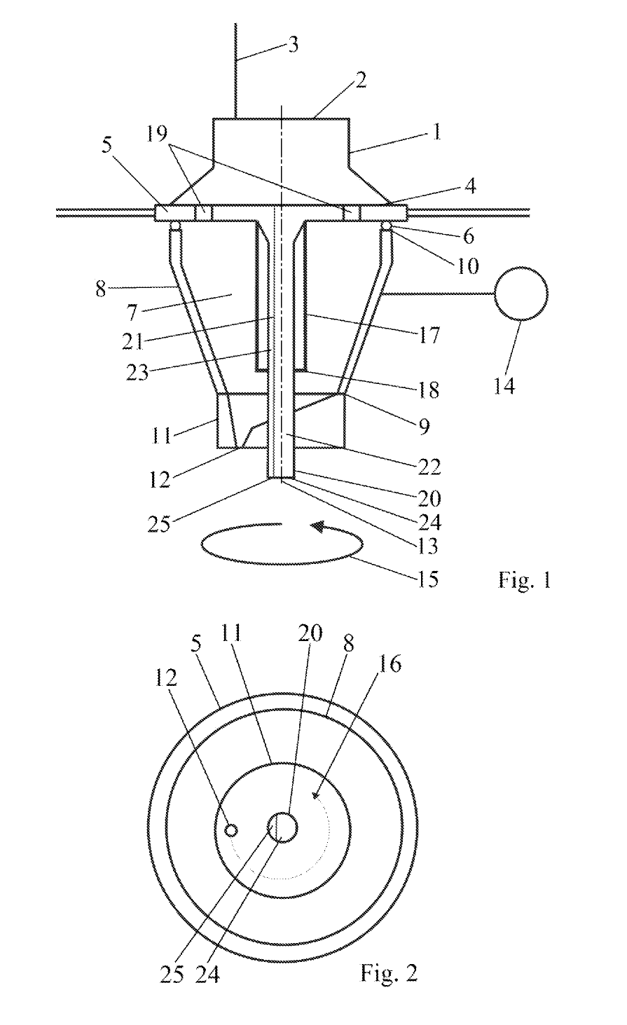

In the case of the first embodiment of the device, the nozzle tube 8 is, as FIG. 1 shows, rotatably mounted at its upper end 10 on the carrier unit 5 of the plasma head 1 by means of a pivot bearing 6. The plasma nozzle 7 is to be set rotating about the longitudinal axis 13 of the device by means of a motor 14 which acts on the nozzle tube 8, as is indicated by the arrow 15 in FIG. 1. As FIG. 2 shows, the outlet opening 12 of the nozzle head 11 for the plasma jet is displaced radially to the longitudinal axis 13 of the plasma nozzle 7, that is to say is arranged excentrically. When the plasma nozzle 7 rotates, the outlet opening 12 of the nozzle head 11 therefore describes a circular path for the plasma jet, as is characterised by the arrow 16 in FIG. 2.

A plasma electrode 17 of the plasma generator which is electrically insulated with respect to the plasma nozzle 7 extends from the carrier unit 5 of the plasma head 1 in the direction of the longitudinal axis 13 of the device into the nozzle tube 8 in such a manner that the tip 18 of the plasma electrode 17 is arranged set back in the direction of the longitudinal axis 13 of the plasma nozzle 7 with respect to the outlet opening 12 of the nozzle head 11 for the plasma jet.

The nozzle tube 8 of the plasma nozzle 7 is connected in terms of flow technology to a working gas channel 19 which is constructed in the carrier unit 5 of the plasma head 1. As can be drawn from the FIGS. 1 and 3, a dosing nozzle 20 for adhesive beads connected to the carrier unit 5 of the plasma head 1 extends from the carrier unit 5 in the direction of the longitudinal axis 13 of the plasma nozzle 7 through the nozzle tube 8 and the nozzle head 11. A dividing wall 21 is provided within the dosing nozzle 20, which dividing wall extends over the axial length of the dosing nozzle 20 and subdivides the latter into two longitudinal chambers 22 and 23 with a discharge opening 24 or 25 in each case at the end of the dosing nozzle 20 opposite the carrier unit 5 of the plasma head 1. The discharge openings 24 and 25 of the longitudinal chambers 22 and 23 of the dosing nozzle 20 are arranged offset towards the outside in the direction of the longitudinal axis 13 of the plasma nozzle 7 beyond the outlet opening 12 of the nozzle head 11 for the plasma jet. As can be seen from the FIGS. 2 and 4, the longitudinal chambers 22 and 23 of the dosing nozzle 20 have different widths. At their upper end which is connected to the carrier unit 5 of the plasma head 1, the longitudinal chambers 22 and 23 of the dosing nozzle 20 are in each case connected in terms of flow technology to attachments 26 for dosing different adhesives (adhesive A or adhesive B), compressed air as well as rinsing fluid and the like, which attachments are accessible from the outside.

The second embodiment of the device arising from FIGS. 3 and 4 is basically constructed in a manner corresponding to the first embodiment, however, the nozzle tube 8 of the plasma nozzle 7 is rigidly connected to the carrier unit 5 of the plasma head 1, as FIG. 3 shows. Furthermore, the outlet opening 12 of the nozzle head 11 for the plasma jet is constructed in a circular manner and encompasses, as FIG. 4 shows, the dosing nozzle 20 which extends through the plasma nozzle 7 in the direction of its longitudinal axis 13.

In the use of the device, the jet of the atmospheric plasma generated by the plasma generator is directed, for plasma pre- and/or aftertreatment of the component surface, through the outlet opening 12 of the nozzle head 11 of the first embodiment, which outlet opening is rotating in a circular path, or through the circular outlet opening 12 of the nozzle head 11 of the second embodiment, which outlet opening is fixed, onto the component surface and the latter is treated with the plasma jet. The bead-like application of an adhesive system or of two adhesive systems, which cure rapidly in each case, is then possible in an efficient manner in one operation by means of the dosing nozzle 20 positioned in the plasma nozzle 7, depending on requirements.

### LIST OF REFERENCE NUMBERS

1 Plasma head
2 Upper side of the plasma head
3 Voltage and Carrier gas supply lines
4 Lower side of the plasma head
5 Carrier unit of the plasma head
6 Pivot bearing
7 Plasma nozzle
8 Nozzle tube
9 Lower end of the nozzle tube
10 Upper end of the nozzle tube
11 Nozzle head
12 Outlet opening for the plasma jet of the nozzle head
13 Longitudinal axis of the device and of the plasma nozzle
14 Motor for rotational drive
15 Arrow characterising rotation
16 Arrow characterising circular path
17 Plasma electrode
18 Tip of the plasma electrode
19 Working gas passage
20 Dosing nozzle
21 Dividing wall of the dosing nozzle
22 Longitudinal chamber of the dosing nozzle for adhesive A
23 Longitudinal chamber of the dosing nozzle for adhesive B
24 Discharge opening of the longitudinal chamber 21
25 Discharge opening of the longitudinal chamber 22
26 Attachments for adhesive dosing, compressed air, rinsing fluid and the like

1. Device for the pre- and/or after treatment of a component surface by means of a plasma jet, particularly by means of a jet of an atmospheric plasma, with a plasma head (1) forming a plasma generator with voltage and carrier-gas supply, to which plasma head a nozzle tube (8) of a plasma nozzle (7) is connected, which plasma nozzle encompasses a plasma electrode (17) of the plasma generator, which is electrically insulated with respect to the plasma nozzle, and is connected in terms of flow technology to a working gas channel (19) and has a nozzle head (11) with an outlet opening (12) for the plasma jet at its end (9) opposite to the plasma head (1), wherein the tip (18) of the plasma electrode (17) is arranged set back in the direction of the longitudinal axis (13) of the plasma nozzle (7) with respect to the outlet opening (12) of the nozzle head (11),
characterized in that
the outlet opening (12) of the nozzle head (11) for the plasma jet of the plasma nozzle (7) is arranged offset in the radial direction to the longitudinal axis (13) thereof, and
a dosing nozzle (20) with at least one discharge opening (24;25) is provided for applying at least
one adhesive, which dosing nozzle is connected to the plasma head (1), extends through the plasma nozzle in the direction of the longitudinal axis (13) of the plasma nozzle (7) and has at least one attachment (26) accessible from outside of the plasma head (1) for dosing the at least one adhesive, the at least one discharge opening (24; 25) of which dosing nozzle is arranged offset outwards in the direction of the longitudinal axis (13) of the plasma nozzle (7), beyond the outlet opening (12) of the nozzle head (11) for the plasma jet and is also arranged offset radially inwards to the longitudinal axis
of the plasma nozzle (7) in relation to the outlet opening (12) for the plasma jet of the nozzle head (11).

2. Device according to claim 1, characterised in that a dividing wall (21) which extends over the axial length of the dosing nozzle is preferably provided within the dosing nozzle (20), by means of which dividing wall the dosing nozzle (20) is subdivided into two longitudinal chambers (22 and 23) which have a discharge opening (24; 25) in each case, which longitudinal chambers in each case have an attachment (26) for the separate dosing of two adhesive components which are different from one another, which attachment can be accessed from outside of the plasma head (1).

3. Device according to claim 1, characterised in that the outlet opening (12) for the plasma jet of the nozzle head (11) of the plasma nozzle (7) is circular.

4. Device according to claim 1, characterised in that the nozzle tube (8) of the plasma nozzle (7) is connected to the plasma head (1) by means of a pivot bearing (6) and is to be set rotating about the longitudinal axis (13) of the plasma nozzle (7) by a motor (14), and in that the outlet opening (12) for the plasma jet of the nozzle head (11) of the plasma nozzle (7) describes a circular path for the plasma jet during the rotation of the plasma nozzle (7).

5. Device according to one of claims 1, characterised in that the dosing nozzle (20) is arranged coaxially in the plasma nozzle (7).
